(19) United States
(12) Patent Application Publication
(10) Pub. No.: US 2026/0062282 A1
(43) Pub. Date: Mar. 5, 2026

(54) MEMS MICROPHONE CHIP

(71) Applicant: AAC ACOUSTIC TECHNOLOGIES (SHENZHEN) CO., LTD., Shenzhen (CN)

(72) Inventors: Kaijie Wang, Shenzhen (CN); Bo Li, Shenzhen (CN); Yu Chen, Shenzhen (CN)

(21) Appl. No.: 18/963,571

(22) Filed: Nov. 28, 2024

Related U.S. Application Data
(63) Continuation of application No. PCT/CN2024/095975, filed on May 29, 2024.

(51) Int. Cl. B81B 3/00; H04R 19/06

(52) U.S. Cl. CPC B81B 3/0051; H04R 19/06; B81B 2201/0257; B81B 2203/0127; B81B 2203/0172; B81B 2203/0307; B81B 2203/0315; B81B 2203/04; H04R 2201/003

(57) ABSTRACT

The present disclosure discloses a MEMS microphone chip. The diaphragm of the MEMS microphone chip is suspended on the substrate by a plurality of elastic connection portions connected with the vibration portion of the diaphragm. The vibration portion includes a central vibration portion and an outer vibration portion connected with the central vibration portion and the plurality of elastic connection portions. The back plate includes an anchor portion extending towards the diaphragm. The anchor portion is fixedly connected with the central vibration portion. Therefore, the diaphragm is mounted on the substrate by the plurality of elastic connection portions. The central vibration portion is anchored to the back plate by the anchor portion. The MEMS microphone chip in the present disclosure has higher reliability.

### FIELD OF THE PRESENT DISCLOSURE

The present disclosure relates to acoustic-electric conversion technologies, especially relates to a MEMS microphone chip.

### DESCRIPTION OF RELATED ART

MEMS microphone chips, such as capacitive MEMS microphone chip, have widely used in acoustic devices.

In related art, the MEMS microphone chip generally includes a substrate having a back cavity, and a diaphragm and a back plate mounted on the substrate. When the sound pressure acts on the diaphragm, a pressure difference between the diaphragm and the back plate drives the diaphragm to move relative to the back plate, thereby causing the capacitance change between the diaphragm and the back plate for realizing the conversion of sound signal to electrical signal. However, the diaphragm is totally spaces apart from the back plate. Owing that a whole annular edge of the diaphragm is fixed to the substrate, the displacement magnitude is excessive resulting in reduction of the reliability of the MEMS microphone chip.

Therefore, it is necessary to provide an improved MEMS microphone chip to overcome the problems mentioned above.

### SUMMARY OF THE INVENTION

One object of the present disclosure is to provide a MEMS microphone chip with higher reliability.

A MEMS microphone chip includes a substrate having a back cavity; a capacitance system mounted on the substrate and covering the back cavity, including: a diaphragm, including: a vibration portion, and a plurality of elastic connection portions extended from an edge of the vibration portion to be fixed to the substrate; a back plate spaced apart from the diaphragm, including an anchor portion extended towards the diaphragm; wherein the vibration portion includes a central vibration portion and an outer vibration portion connected with the central vibration portion and the plurality of elastic connection portions; the anchor portion is fixedly connected with the central vibration portion.

As an improvement, the back plate includes an insulation layer and an electrode layer arranged on a surface of the insulation layer towards the diaphragm; the electrode layer comprises an electrode portion moved relative to the diaphragm for generating an electrical signal, and an isolation portion electrically isolated from the electrode portion, the anchor portion extends from the isolation portion towards the diaphragm.

As an improvement, the back plate includes an insulation layer and an electrode layer arranged on a surface of the insulation layer towards the diaphragm; the anchor portion is formed on the isolation layer.

As an improvement, the insulation layer includes an anchor area malposed with the electrode layer along a vibration direction of the diaphragm; the anchor area is configured to dent towards the diaphragm for forming the anchor portion.

As an improvement, the insulation layer includes an anchor area malposed with the electrode layer along a vibration direction of the diaphragm; the anchor portion is formed by extending from the anchor area to pass through the electrode layer.

As an improvement, the plurality of elastic connection portions is spaced arranged along an edge of the outer vibration portion; each of the plurality of elastic connection portions includes a first connection portion connected with the edge of the outer vibration portion, a second connection portion connected with the substrate, and an elastic portion connected the first connection portion with the second connection portion, the elastic portion comprises a plurality bending portions interconnected with each other; each of the plurality bending portions is S-shaped.

As an improvement, the second connection portion is connected with two of the plurality bending portions, the vibration portion of the diaphragm is circular; the two of the plurality bending portions are axisymmetric relative to a central axis along a radial direction of the second connection portion.

As an improvement, the first connection portion is connected to an end of the bending portion away from the second connection portion.

As an improvement, further including a support portion mounted on the substrate; an end of the elastic connection portion is fixed to the outer vibration portion, the other end of the elastic connection portion is fixed to the support portion.

### BRIEF DESCRIPTION OF THE DRAWINGS

The accompanying drawings illustrate embodiments and constitute part of the specification, and together with the specification, serve to explain exemplary embodiments of the present disclosure. The accompanying drawings shown are only for illustrative purposes and do not limit the scope of the claims. In all the accompanying drawings, same reference signs refer to similar but not necessarily identical elements.

FIG. 1 is an isometric view of a MEMS microphone chip in accordance with an exemplary embodiment of the present disclosure.

FIG. 2 is an exploded view of the MEMS microphone chip in FIG. 1.

FIG. 3 is a section view of the MEMS microphone chip taken along line A-A in FIG. 1.

FIG. 4 is a top view of a diaphragm and a second support portion of the MEMS microphone chip in FIG. 1.

FIG. 5 is a section view of an anchor portion of a back late of the MEMS microphone chip in accordance with an exemplary embodiment of the present disclosure.

FIG. 6 is a section view of an anchor portion of a back late of the MEMS microphone chip in accordance with another exemplary embodiment of the present disclosure.

### DETAILED DESCRIPTION OF THE EXEMPLARY EMBODIMENTS

In order to make the inventive objectives, features, and advantages of the present disclosure more understandable, the technical solutions in embodiments of the present disclosure will be described clearly and completely below with reference to the accompanying drawings in the embodiments of the present disclosure. It is apparent that the described embodiments are merely some of rather than all of the embodiments of the present disclosure. All other embodiments acquired by those skilled in the art without creative efforts based on the embodiments in the present disclosure shall fall within the protection scope of the present disclosure.

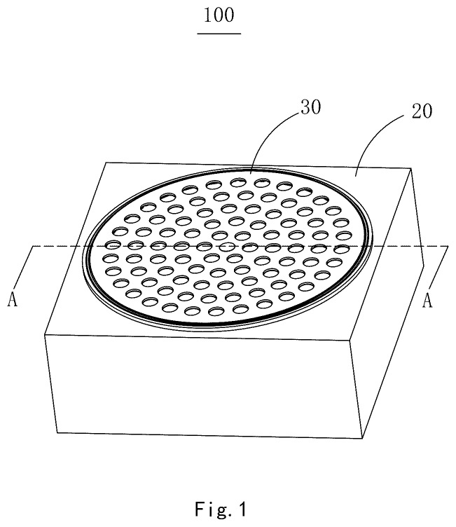

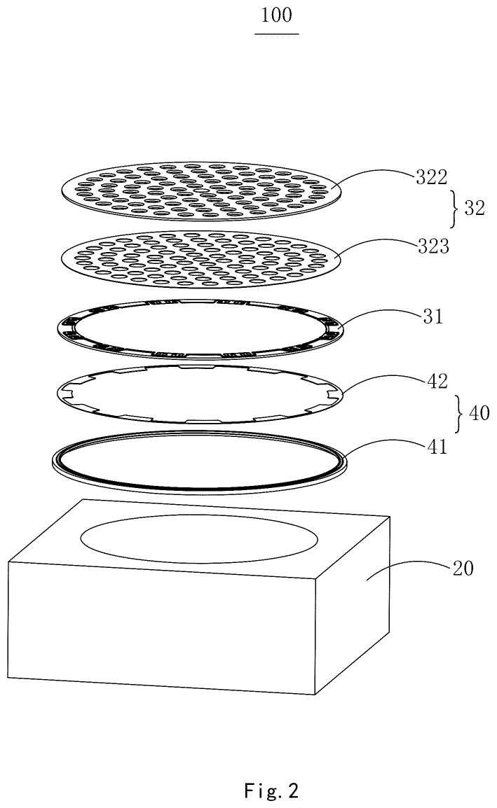

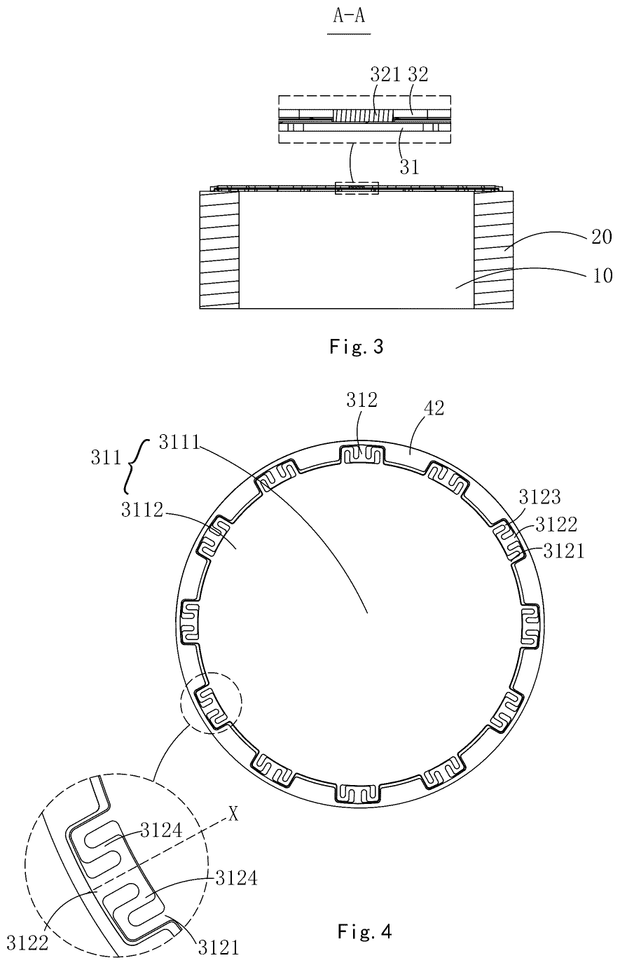

Please refer to FIGS. 1-4, a MEMS microphone chip 100 provided by an exemplary embodiment of the present disclosure includes a substrate 20 having a back cavity 10, and a capacitance system 30 mounted on the substrate 20 and covering the back cavity 10. The capacitance system 30 includes a diaphragm 31 and a back plate 32 arranged at an interval along a vibration direction of the diaphragm 31. When the sound pressure acts on the diaphragm 31, a capacitance between the diaphragm and the back plate changes for detecting acoustic signal. In one embodiment, the back plate 32 is located on a side of the diaphragm 31 away from the substrate 20.

Specifically, the diaphragm 31 includes a vibration portion 311 and a plurality of elastic connection portions 312 extended from an edge of the vibration portion 31 to be fixed to the substrate 20. The diaphragm 31 is suspended above the back cavity 10 through the plurality of elastic connection portions 312. Moreover, the vibration portion 311 includes a central vibration portion 3111 and an outer vibration portion 3112 connected with the central vibration portion 3111 and the plurality of elastic connection portions 312. The back plate 32 includes an anchor portion 321 extended towards the diaphragm 31. The anchor portion 321 is fixed to the central vibration portion 3111. By providing the anchor portion 321 for connecting the central vibration portion 3111 of the diaphragm 31 with the back plate 32, the excessive displacement magnitude of the diaphragm 31 could be effectively avoided to improve the reliability of the diaphragm 31.

In addition, as shown in FIGS. 1-3 and FIG. 6, the back plate 32 includes an insulation layer 322 and an electrode layer 323 arranged on a surface of the insulation layer 322 towards the diaphragm 31. The electrode layer 323 includes an electrode portion 3231 moved relative to the diaphragm 31 for generating an electrical signal, and an isolation portion 3232 electrically isolated from the electrode portion 3231. The anchor portion 321 extends from the isolation portion 3232 towards the diaphragm 31.

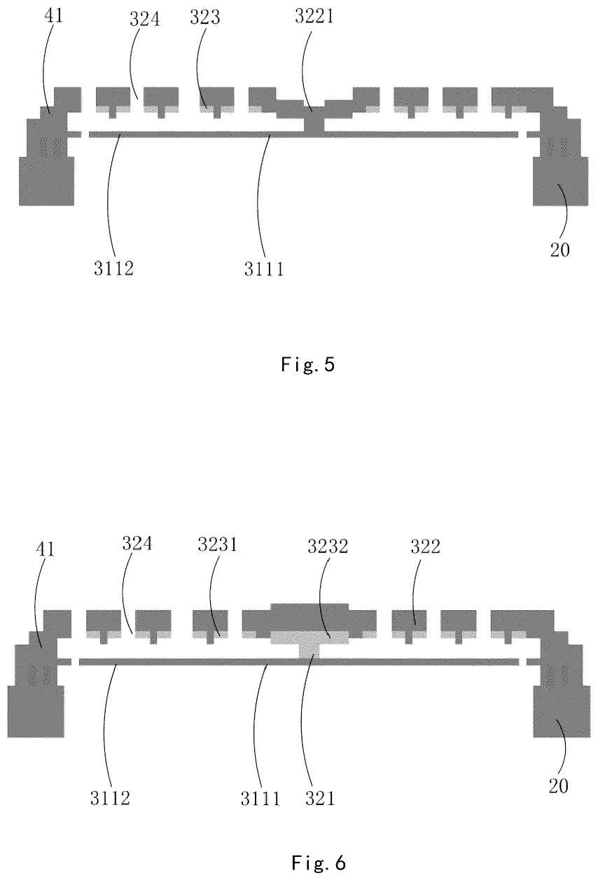

In another embodiment, as shown in FIGS. 1-3 and FIG. 5, the anchor portion 321 is formed on the insulation layer 322. Specifically, the insulation layer 322 includes an anchor area 3221 malposed with the electrode layer 323 along the vibration direction. At least partial anchor area 3221 is served as the anchor portion 321 by denting towards the diaphragm 21. The anchor portion 321 extends from the anchor area 3221 and passes through the electrode layer 323 to be fixed to the diaphragm 31.

As shown in FIG. 4, the plurality of elastic connection portions 312 is spaced arranged along an edge of the outer vibration portion 3112. Each of the plurality of elastic connection portions 312 includes a first connection portion 3121 connected with the edge of the outer vibration portion 3112, a second connection portion 3122 connected with the substrate 20, and an elastic portion 3123 connected the first connection portion 3121 with the second connection portion 3122. Furthermore, the elastic portion 3123 includes a plurality bending portions 3124 interconnected with each other. Each of the plurality bending portions 3124 is S-shaped.

In addition, the second connection portion 3122 is connected with two of the plurality bending portions 3124. The vibration portion 311 of the diaphragm 31 is circular. The two of the plurality bending portions 3124 are axisymmetric relative to a central axis X along a radial direction of the second connection portion 3122. The first connection portion 3121 is connected to an end of the bending portion 3124 away from the second connection portion 3122.

The MEMS microphone chip 100 further includes a support portion 40 mounted on the substrate 20. An end of the elastic connection portion 312 is fixed to the outer vibration portion 3112, the other end of the elastic connection portion 312 is fixed to the support portion 40. Concretely, the support portion 40 includes a first support portion 41 mounted on the substrate 20, and a second support portion 42 mounted on the first support portion 41. The first support portion 41 is configured to suspend the back plate 32. The second support portion 42 is configured to suspend the diaphragm 31.

Besides, a plurality of sound holes 324 is provided on the back plate 32 penetrating thereon along the vibration direction of the diaphragm 31. The anchor portion is provided on an area on the back plate 32 without sound holes 324.

Compared with the related art, the diaphragm of the MEMS microphone chip is suspended on the substrate by a plurality of elastic connection portions connected with the vibration portion of the diaphragm. The vibration portion includes a central vibration portion and an outer vibration portion connected with the central vibration portion and the plurality of elastic connection portions. The back plate includes an anchor portion extending towards the diaphragm. The anchor portion is fixedly connected with the central vibration portion. Therefore, the diaphragm is mounted on the substrate by the plurality of elastic connection portions. The central vibration portion is anchored to the back plate by the anchor portion. In this manner, the reliability of the MEMS microphone chip is effectively improved.

It is to be understood, however, that even though numerous characteristics and advantages of the present exemplary embodiments have been set forth in the foregoing description, together with details of the structures and functions of the embodiments, the disclosure is illustrative only, and changes may be made in detail, especially in matters of shape, size, and arrangement of parts within the principles of the invention to the full extent indicated by the broad general meaning of the terms where the appended claims are expressed.

What is claimed is:

1. A MEMS microphone chip comprising:
a substrate having a back cavity;
a capacitance system mounted on the substrate and covering the back cavity, including:
a diaphragm, including:
a vibration portion, and
a plurality of elastic connection portions extended from an edge of the vibration portion to be fixed to the substrate; and
a back plate spaced apart from the diaphragm, including an anchor portion extended towards the diaphragm; wherein
the vibration portion includes a central vibration portion and an outer vibration portion connected with the central vibration portion and the plurality of elastic connection portions; the anchor portion is fixedly connected with the central vibration portion.

2. The MEMS microphone chip as described in claim 1, wherein the back plate comprises an insulation layer and an electrode layer arranged on a surface of the insulation layer towards the diaphragm; the electrode layer comprises an electrode portion moved relative to the diaphragm for generating an electrical signal, and an isolation portion electrically isolated from the electrode portion, the anchor portion extends from the isolation portion towards the diaphragm.

3. The MEMS microphone chip as described in claim 1, wherein the back plate comprises an insulation layer and an electrode layer arranged on a surface of the insulation layer towards the diaphragm; the anchor portion is formed on the isolation layer.

4. The MEMS microphone chip as described in claim 3, wherein the insulation layer comprises an anchor area malposed with the electrode layer along a vibration direction of the diaphragm; the anchor area is configured to dent towards the diaphragm for forming the anchor portion.

5. The MEMS microphone chip as described in claim 3, wherein the insulation layer comprises an anchor area malposed with the electrode layer along a vibration direction of the diaphragm; the anchor portion is formed by extending from the anchor area to pass through the electrode layer.

6. The MEMS microphone chip as described in claim 1, wherein the plurality of elastic connection portions is spaced arranged along an edge of the outer vibration portion; each of the plurality of elastic connection portions includes a first connection portion connected with the edge of the outer vibration portion, a second connection portion connected with the substrate, and an elastic portion connected the first connection portion with the second connection portion, the elastic portion comprises a plurality bending portions interconnected with each other; each of the plurality bending portions is S-shaped.

7. The MEMS microphone chip as described in claim 6, wherein the second connection portion is connected with two of the plurality bending portions, the vibration portion of the diaphragm is circular; the two of the plurality bending portions are axisymmetric relative to a central axis along a radial direction of the second connection portion.

8. The MEMS microphone chip as described in claim 7, wherein the first connection portion is connected to an end of the bending portion away from the second connection portion.

9. The MEMS microphone chip as described in claim 1, further comprising a support portion mounted on the substrate; an end of the elastic connection portion is fixed to the outer vibration portion, the other end of the elastic connection portion is fixed to the support portion.
